(19) United States
(12) Patent Application Publication
(10) Pub. No.: US 2004/0245914 A1
(43) Pub. Date: Dec. 9, 2004

(54) Image display apparatus

(76) Inventors: Shigeo Takenaka, Fukaya-shi (JP); Sachiko Hirahara, Fukaya-shi (JP); Masaru Nikaido, Yokosuka-shi (JP); Satoshi Ishikawa, Fukaya-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/804,066

(22) Filed: Mar. 19, 2004

Related U.S. Application Data
(63) Continuation of application No. PCT/JP02/09566, filed on Sep. 18, 2002.

(30) Foreign Application Priority Data
Sep. 19, 2001 (JP) 2001-285812

(51) Int. Cl. H01J 1/62; H01L 21/331; H01J 63/04

(52) U.S. Cl. 313/495

(57) ABSTRACT

An image display apparatus includes a faceplate having an image display surface, and a rear plate arranged opposite to the faceplate with a gap, and provided with a plurality of electron sources which excite the image display surface. A grid and a plurality of spacers, which keeps the distance between the plates, are provided between the faceplate and the rear plate. First spacers have a height lower than that of the second spacers.

### CROSS-REFERENCE TO RELATED APPLICATIONS

This is a Continuation Application of PCT Application No. PCT/JP02/09566, filed Sep. 18, 2002, which was not published under PCT Article 21(2) in English.

This application is based upon and claims the benefit of priority from prior Japanese Patent Application No. 2001-285812, filed Sep. 19, 2001, the entire contents of which are incorporated herein by reference.

### BACKGROUND OF THE INVENTION

1. Field of the Invention

The present invention relates to an image display apparatus having substrates opposing to each other, and a plurality of electron sources arranged on an inner surface of one of the substrate.

2. Description of the Related Art

In recent years, there has been a demand for an image display apparatus for high-quality broadcast or high-resolution required therefor. As regards the screen display performance of the apparatus, more exact performance has been demanded. To meet these demands, it is indispensable to provide a flat and high-resolution screen surface. At the same time, the screen must be light and thin.

As an image display apparatus that meets the above demands, a flat display surface, such as a field emission display (hereinafter referred to as “FED”), has attracted attention. The FED has a front substrate and a rear substrate opposing to each other at a predetermined interval therebetween. The peripheries of the substrates are joined together directly or via a rectangular flame-shaped side wall, thereby forming a vacuum envelope. A phosphor screen is formed on the inner surface of the front substrate, while a plurality of electron emitting elements are formed on the inner surface of the rear substrate. The electron emitting elements serve as electron sources, which excite the phosphor to emit light.

Further, to support an atmospheric pressure load exerted on the rear substrate and the front substrate, a plurality of support members are arranged between the substrates. In this FED, electron beams emitted from the electron emitting elements are radiated on the phosphor screen, so that the phosphor screen emits light. Thus, an image is displayed.

In the FED, the electron emitting element has a size of the micrometer order, and the distance between the front substrate and the rear substrate can be set in the millimeter order. Therefore, the FED can realize higher resolution, and more reduction in weight and thickness as compared to a cathode ray tube (CRT) used in the conventional television or computer display.

To obtain a practical display characteristic in the image display apparatus as described above, it is necessary to use the same phosphor as those used in the conventional cathode ray tube and set the anode voltage to several kilovolts or higher. However, from the viewpoint of the resolution, the characteristic of the support members, the manufacturability and the like, the distance between the front substrate and the rear substrate cannot be so large but need be about 1 to 2 mm. Therefore, an intense electric field is inevitably formed between the front substrate and the rear substrate, resulting in a problem of discharge (dielectric breakdown) between the substrates.

When discharge occurs, the electron emitting elements provided on the rear substrate or the phosphor layer on the side of the front substrate may be damaged or deteriorated, with the result that the display grade may be lowered. The discharge is not desirable, since it may cause defect in a product. Therefore, the front substrate or the rear substrate needs to have a voltage resistant structure against discharge. In this case, the manufacturing cost will increase.

### BRIEF SUMMARY OF THE INVENTION

The present invention is made in consideration of the above circumstances, and its object is to provide an image display apparatus having a high voltage-resistance to discharge and improved image grade.

To achieve the above object, according to an aspect of the present invention, there is provided an image display apparatus comprising: a first substrate having an image display surface; a second substrate arranged opposite to the first substrate with a gap therebetween, and provided with a plurality of electron sources which excite the image display surface; a grid provided between the first and second substrates, and having a first surface opposing the first substrate, a second surface opposing the second substrate and a plurality of beam passage apertures respectively opposing the electron sources; a plurality of first spacers which are columnar, protrude from the first surface of the grid and abut against the first substrate; and a plurality of second spacers which are columnar, protrude from the second surface of the grid and abut against the second substrate, the first spacers having a height lower than that of the second spacers.

In the image display apparatus constructed as described above, the grid is interposed between the first and second substrates, and the first spacers have the height lower than that of the second spacers. Accordingly, the grid is located nearer to the side of the first substrate than the second substrate. Therefore, even if discharge occurs from the first substrate side, the electron sources provided on the second substrate can be prevented from damage by discharge.

According to another aspect of the present invention, there is provided an image display apparatus comprising a first substrate having an image display surface; a second substrate arranged opposite to the first substrate with a gap therebetween, and provided with a plurality of electron sources which excite the image display surface; a grid provided between the first and second substrates, and having a first surface opposing the first substrate, a second surface opposing the second substrate and a plurality of apertures respectively opposing the electron sources; a plurality of first spacers which are columnar, protrude from the first surface of the grid and abut against the first substrate; and a plurality of second spacers which are columnar, protrude from the second surface of the grid and abut against the second substrate, each of the first spacers abutting against the first substrate via a height buffer layer having a lower resistance than that of the first spacers.

In the image display apparatus constructed as described above, since the height buffer layer is provided, even if the heights of the first spacers vary, the variance is absorbed by the buffer layer. Therefore, the first spacers can reliably abut against and contact with the first substrate. Accordingly, the electrical conduction between the first substrate and the first spacers is ensured, so that the discharge phenomenon can be suppressed.

### BRIEF DESCRIPTION OF THE SEVERAL VIEWS OF THE DRAWING

The accompanying drawings, which are incorporated in and constitute a part of the specification, illustrate an embodiment of the invention, and together with the general description given above and the detailed description of the embodiment given below, serve to explain the principles of the invention.

FIG. 1 is a perspective view showing an SED according to an embodiment of the present invention;

FIG. 2 is a perspective view of the SED cross-sectioned along the line II-II in FIG. 1;

FIG. 3 is an enlarged sectional view of the SED;

FIG. 4 is a side view showing a part of a spacer assembly formed in a process of manufacturing the SED;

FIG. 5 is a sectional view showing a step for forming a high resistant film on a second spacer of the spacer assembly in the aforementioned manufacturing process; and

FIG. 6 is a sectional view schematically showing a step of joining a face plate, a spacer assembly and a rear place in the aforementioned manufacturing step.

### DETAILED DESCRIPTION OF THE INVENTION

An embodiment, in which the present invention is applied to a surface-conduction electron-emitter display (hereinafter referred to as “SED”), will be described in detail with reference to the drawings.

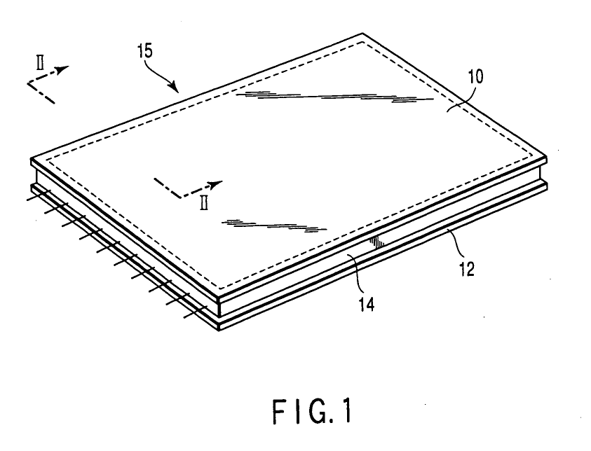

As shown in FIGS. 1 to 3, the SED has a rear plate 12 and a faceplate 10, each formed of a rectangular glass and serving as a transparent insulating substrate. These plates are arranged opposite to each other with a distance of about 1.0 to 2.0 mm. The rear plate 12 is slightly larger than the faceplate 10. The peripheries of the rear plate 12 and the faceplate 10 are adhered to each other via a rectangular flame-shaped side wall 14. Thus, a flat rectangular vacuum envelope 15 is constructed.

A phosphor screen 16, as an image display surface, is formed on the inner surface of the faceplate 10, which functions as a first substrate. The phosphor screen 16 comprises red, blue and green phosphor layers and a black light-shielding layer arranged side by side. The phosphor layers are formed like stripes or dots. Further, a metal back 17 made of aluminum or the like is formed on the phosphor screen 16. A transparent conductive film formed of, for example, ITO, ATO or “Nesa” (SnO2), may be provided between the faceplate 10 and the phosphor screen.

The rear plate 12 functions as a second substrate. A number of electron emitting elements 18, as electron sources that excite the phosphor layers of the phosphor screen 16, are provided on the inner surface of the rear plate 12. Each of the electron emitting elements 18 emits an electron beam. These electron emitting elements 18 are arranged so as to respectively correspond to pixels, in a plurality of rows and a plurality of columns. Each electron emitting element 18 comprises an electron emitting section (not shown) and a pair of element electrodes which apply a voltage to the electron emitting section. Further, a number of wires (not shown) to apply a voltage to the electron emitting elements 18 are arranged in a matrix on the rear plate 12.

The side wall 14, which functions as a joint member, is sealed to the peripheries of the rear plate 12 and the faceplate 10 by a sealing material 20, such as a low-melting-point metal. As a result, it joins the faceplate and the rear plate to each other.

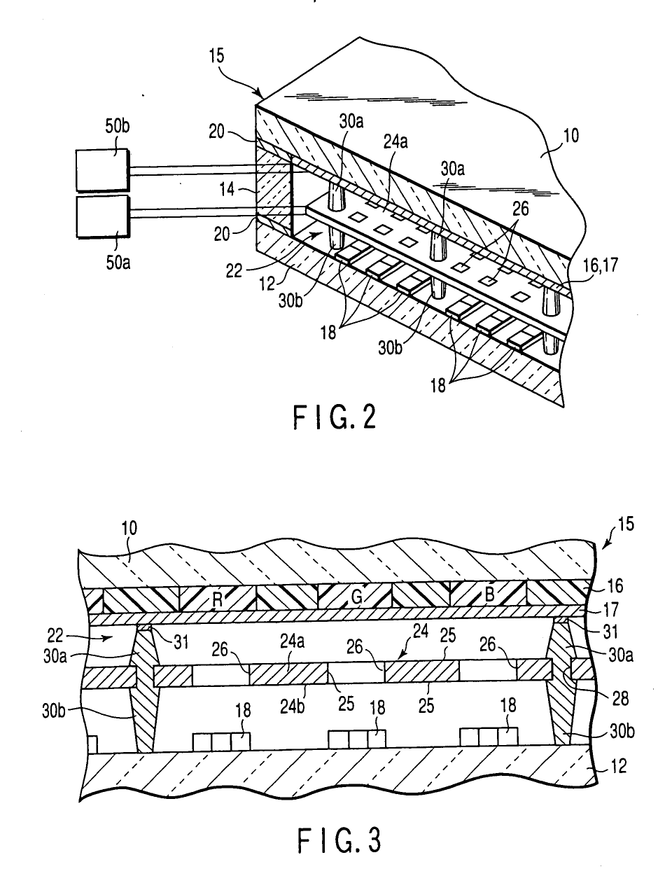

Further, as shown in FIGS. 2 and 3, the SED has a spacer assembly 22 arranged between the faceplate 10 and the rear plate 12. In this embodiment, the spacer assembly 22 comprises a plate-shaped grid 24 and a plurality of columnar spacers integrally protruded from both surfaces of the grid.

More specifically, the grid 24 has a first surface 24a facing the inner surface of the faceplate 10 and a second surface 24b facing the inner surface of the rear plate 12. The grid 24 is arranged parallel with these plates. It has a number of electron beam passage apertures 26 and a plurality of spacer holes 28, which have been formed by etching or the like. The electron beam passage apertures 26 are arranged to respectively face the electron emitting elements 18. The spacer holes 28 are arranged at a predetermined pitch, and each of them is located between adjacent electron beam apertures 26.

The grid 24 is formed of, for example, a nickel-based metal plate containing 45-55 wt % iron. The thickness of the grid is 0.1-0.25 mm. Black film containing an element forming the metal plate, such as Fe₃O₄ or NiFe₂O₄ black film, is formed on the surface of the grid 24 by oxidizing the grid. Further, the surface of the grid 24 is coated with a high resistance material made of glass or ceramics. The coated material is sintered, thereby forming a high-resistance film 25. The grid 24 may be formed of an iron-nickel metal plate, to which an element such as an aluminum that is easily selectively oxidized and forms an insulative oxide film, is added. This metal plate is heat treated, so that an insulating film made of alumina, etc., may be formed on the surface.

The electron beam passage apertures 26 have a rectangular shape of, for example, 0.15-0.25 mm×0.15-0.25 mm. The spacer holes 28 have a diameter of, for example, about 0.2-0.5 mm. The high resistance film 25 described above is also formed on the inner surface of every electron beam passage aperture 26.

First spacers 30a are integrally protruded from the first surface 24a of the grid 24, so as to overlap the respective spacer holes 28. Distal ends of the first spacers 30a abut against the inner surface of the faceplate 10 via the metal back 17 and the black light-shielding layer of the phosphor screen 16. In this embodiment, the distal ends of the first spacers 30a are adhered to the metal back 17 via an indium layer 31, which functions as a height buffer layer, and electrically connected to the metal back 17. The height buffer layer is formed of a material, which has electrical conductivity and a lower electric resistance than the electric resistance of the first spacers 30a.

Second spacers 30b are integrally protruded from the second surface 24b of the grid 24, so as to overlap the respective spacer holes 28. Distal ends thereof abut against the inner surface of the rear plate 12. Each spacer hole 28 and the corresponding first and second spacers 30a and 30b are located in alignment with one another. The first and second spacers are integrally connected to each other via the spacer hole 28.

Each of the first and second spacers 30a and 30b has a tapered shape, the diameter of which is reduced toward the distal end from the side of the grid 24.

For example, each of the first spacers 30a has a diameter of about 0.4 mm at the proximal end located on the grid 24 side, a diameter of about 0.3 mm at the distal end, and a height of about 0.4 mm. Each of the second spacers 30b has a diameter of about 0.4 mm at the proximal end located on the grid 24 side, a diameter of about 0.25 mm at the distal end, and a height of about 1.0 mm. Thus, the height of the first spacer 30a is lower than that of the second spacer 30b; the height of the second spacer is about 4/3 or more, preferably twice or more of the height of the first spacer.

The first spacer 30a and the second spacer 30b are integrally provided and coaxially aligned with the spacer hole 28. Accordingly, the first and second spacers are connected to each other via the spacer hole, and formed integral with the grid 24 so as to sandwich the grid 24 from both sides.

A high resistance coating film, made of tin oxide and antimony oxide, is formed on the outer surface of each of the second spacer 30b. The high resistance film is less resistant than the surface resistance of the first spacer 30a, but is not conductive.

As shown in FIGS. 2 and 3, the spacer assembly 22 constructed as described above is arranged between the faceplate 10 and the rear plate 12. The first and second spacers 30a and 30b abut against the inner surface of the faceplate 10 and the rear plate 12, thereby supporting the atmospheric load exerted on the plates and maintaining the distance between the plates at a predetermined value.

As shown in FIG. 2, the SED has voltage supply sections 50a and 50b, which apply a predetermined voltage to the grid 24 and the metal back 17 of the faceplate 10. In the SED, when an image is to be displayed, an anode voltage is applied to the phosphor screen 16 and the metal back 17. The electron beams discharged from the electron emitting elements 18 are accelerated by the anode voltage, and collide against the phosphor screen 16. As a result, the phosphor layers of the phosphor screen 16 are excited and emit light, so that an image is displayed.

The following is an explanation of a method for manufacturing the spacer assembly 22 constructed as described above and an SED having the same.

When the spacer assembly 22 is manufactured, first, the grid 24 of a predetermined size, and first and second rectangular plate molds (not shown) of substantially the same size as the grid are prepared. In the grid 24, the electron beam passage apertures and the spacer holes 28 have been formed in advance. The overall grid is selectively oxidized by oxidation treatment, thereby forming a black film on the surface of the grid including the inner surfaces of the electron beam passage apertures 26 and the spacer holes 28. Further, the black film is spray-coated with a liquid in which glass minute particles are dispersed. The coat is dried and sintered, thereby forming a high-resistance film.

Each of the first and second molds has a plurality of through holes corresponding to the spacer holes 28 of the grid 24. The first mold is formed of a lamination of, for example, three metal thin plates. Each metal thin plate is a plate made of the same metal as the material of the grid, and about 0.25-0.3 mm thick. A plurality of tapered through holes are formed in each metal thin plate. The through holes formed in each metal thin plate have a different diameter from those of the other metal thin plates. The three metal thin plates are laminated such that the through holes substantially coaxially aligned in the order of the largest diameter of the through holes, and diffusion-joined with one another in a vacuum or reductive atmosphere. Thus, the first mold of the thickness of 0.5-0.6 mm as a whole is formed. Each through hole is defined by combining two through holes and has a stepped tapered inner surface.

On the other hand, the second mold is formed of a lamination of, for example, five metal thin plates, like the first mold. Each through hole formed in the second mold is defined by five tapered through holes and has a stepped tapered inner surface. In the first and second molds, at least the inner surface of each through hole is coated with resin, which has a decomposition temperature lower than the thermal decomposition temperature of the organic component in glass paste.

In the process of manufacturing the spacer assembly, the first mold is brought into close contact with the first surface 24a of the grid, such that the larger diameter side of each through hole is located on the grid 24 side, and the through holes are respectively positioned in alignment with the spacer holes 28 of the grid. Likewise, the second mold is brought into close contact with the second surface 24b of the grid, such that the larger diameter side of each through hole is located on the grid 24 side, and the through holes are respectively positioned in alignment with the spacer holes 28 of the grid. Then, the first mold, the grid 24 and the second mold are fixed to one another by using a cramper (not shown) or the like.

Thereafter, a paste-like spacer forming material is supplied from the outer surface side of the first mold, for example. The through holes of the first mold, the spacer holes 28 of the grid 24 and the through holes of the second mold are filled with the spacer forming material. The spacer forming material is made of glass paste containing at least an ultraviolet cure binder (organic component) and a glass filler.

Then, ultraviolet (UV) as radiation is applied to the filled spacer forming material from the outer sides of the first and second molds, so that the spacer forming material is UV cured. If necessary, thermal curing may be used instead of UV curing as auxiliary means.

Further, in the state where the first and second molds are tightly in contact with the grid, these are thermally treated in a heating furnace. The resin is decomposed at a temperature lower than the thermal decomposition temperature of the organic component of the glass paste and higher than the decomposition start temperature of the resin applied to every through hole of the molds. Thus, a gap is defined between the resin and the cured glass paste.

Thereafter, the first and second molds and the grid 24 are cooled to a predetermined temperature. Then, the first and second molds are removed from the grid 24. Finally, after the binder is volatilized out of the spacer forming material, the spacer forming material is sintered by a thermal treatment at about 500-550° C. for 30 minutes to an hour. As a result, a base of the spacer assembly 22 is completed, in which the first and second spacers 30a and 30b are incorporated on the grid 24.

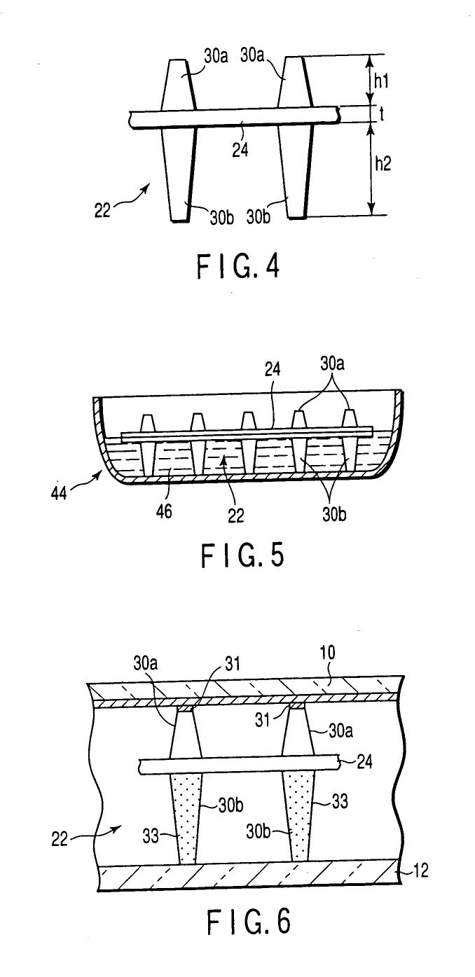

In the spacer assembly 22 thus completed, as shown in FIG. 4, the thickness of the grid 24 is 0.1 mm, each first spacer 30a has the diameter of about 0.4 mm at the proximal end of the grid 24 side, the diameter of about 0.3 mm at the distal end and the height h1 of about 0.4 mm. Each second spacer 30b has the diameter of about 0.4 mm at the proximal end of the grid 24 side, the diameter of about 0.25 mm at the distal end and the height h2 of about 1.0 mm.

Then, as shown in FIG. 5, the second spacer 30b portion of the spacer assembly 22 is immersed in a coating liquid 46 contained in a container 44 made of polypropylene. A liquid, in which tin oxide and antimony oxide particles are dispersed, was used as the coating liquid 46. The spacer assembly 22 is drawn out of the container 44, thereafter, dried and sintered, thereby forming a high resistance film 33 on the surface of the second spacers 30b. As a result, in the spacer assembly 22, the surface resistance of the second spacer 30b is set to a value smaller than the surface resistance of the first spacer 30a. In this embodiment, the surface resistance of the first spacer 30a is, for example, 5×10¹³Ω, while the surface resistance of the second spacer 30b is 5×10⁸.

The spacer assembly 22 is completed through the above steps.

To manufacture an SED using the spacer assembly 22 manufactured as described above, the rear plate 12 and the faceplate 10 are prepared in advance. The electron emitting elements 18 have been provided on the rear plate 12 and the side wall 14 has been joined thereto. The phosphor screen 16 and the metal back 17 have been provided on the faceplate 10.

Then, as shown in FIG. 6, paste containing indium powder is applied to the distal ends of the respective first spacers 30a. After the paste is dried, the spacer assembly 22 is positioned on the rear plate 12. In this state, the rear plate 12 and the faceplate 10 are disposed in a vacuum chamber, and the vacuum chamber is evacuated. Thereafter, the faceplate 10 is joined to the rear plate 12 via the side wall 14. At the same time, the indium powder is melted, so that the distal ends of the first spacers 30a are bonded to the faceplate 10. As a result, the SED having the spacer assembly 22 is manufactured.

With the SED constructed as described above, the grid 24 is arranged between the faceplate 10 and the rear plate 12, and the height of the first spacers 30a is lower than that of the second spacers 30b. Accordingly, the grid 24 is located nearer to the side of the faceplate 10 than the rear plate 12. Therefore, even if discharge occurs from the faceplate 10 side, the discharge is blocked by the grid 24, and the electron emitting elements 18 provided on the rear plate, 12 can be prevented from damage due to discharge. Therefore, it is possible to obtain the SED that has a high voltage-resistance to discharge and improved image grade.

A sample SED and an SED according to this embodiment were prepared. The sample SED has a spacer assembly in which the first spacer on the faceplate side is higher than the second spacer on the rear plate side. These SED were operated for 1000 hours and thereafter the damages in the electron emitting elements were compared. As a result, the damage in the electron emitting elements in the SED of this embodiment was 40% less as compared to the sample SED.

Moreover, according to the SED described-above, the height of the first spacer 30a provided on the faceplate 10 side is lower than that of the second spacer 30b on the rear plate 12 side. With this structure, even if the voltage applied to the grid 24 is higher than the voltage applied to the faceplate 10, the electrons generated from the electron emitting elements 18 can surely arrive at the phosphor screen side.

Further, according to the SED of this embodiment, since the height buffer layers are provided, even if the heights of the first spacers 30a vary, the variance is absorbed by the buffer layers. Therefore, the first spacers can reliably abut against and contact with the faceplates 10. Accordingly, the distance between the faceplate 10 and the rear plate 12 can be uniform substantially in the overall region owing to the first and second spacers 30a and 30b. Moreover, the electrical conduction between the faceplate 10 and the first spacers 30a is ensured, so that the electrical charge of the spacers can be dissipated to the faceplate 10 side. As a result, the discharge phenomenon can be suppressed.

An SED according to this embodiment and a sample SED having no height buffer layer were prepared, and the states of occurrence of discharge phenomenon were compared. As a result, discharge occurred in the sample SED, whereas the discharge phenomenon due to the gap between the faceplate and the first spacers did not occur in the SED of this embodiment.

Further, according to the SED of this embodiment, the surface resistance of the second spacers 30b located on the electron source side is smaller than the surface resistance of the first spacers 30a. Therefore, the second spacers 30b are prevented from charge, so that the displacement of the electron beams due to the charge of the second spacers can be reduced. As a result, it is possible to display an image with an improved color purity.

An SED according to this embodiment and a sample SED having second spacers of the same surface resistance as that of the first spacers were prepared, and the amounts of displacement of electron beams were compared. As a result, in the SED of this embodiment, the displacement of the electron beams passing by the spacers was about 70% less and the color purity of the displayed image was about 10% improved as compared to the sample SED.

The present invention is not limited to the above embodiment, but can be variously modified within the scope of the invention. For example, the spacer forming material is not limited to the glass paste described above, but may be suitably chosen as needed. The diameters and heights of the spacers, the dimensions and material of the other structural elements, etc., may be suitably chosen as needed. Further, the high resistance film provided on the grid surface and the second spacers is not limited to tin oxide and antimony oxide, but may be suitably chosen as needed.

The electron source is not limited to a surface conductive-type electron emitting element. For example, a field discharge-type, a carbon nano tube, etc. may be suitably chosen. Further, the present invention is not limited to the SED described above, but may be applied to various display apparatuses, such as FED and PDP.

What is claimed is:

1. An image display apparatus comprising:
a first substrate having an image display surface;
a second substrate arranged opposite to the first substrate with a gap therebetween, and provided with a plurality of electron sources which excite the image display surface;
a grid provided between the first and second substrates, and having a first surface opposing the first substrate, a second surface opposing the second substrate and a plurality of beam passage apertures respectively opposing the electron sources;
a plurality of first spacers which are columnar, protrude from the first surface of the grid and abut against the first substrate; and
a plurality of second spacers which are columnar, protrude from the second surface of the grid and abut against the second substrate,
the first spacers having a height lower than that of the second spacers.

2. The image display apparatus according to claim 1, wherein the first spacers abut against the first substrate via a height buffer layer having a lower resistance than that of the first spacers.

3. The image display apparatus according to claim 1, wherein the second spacers have a lower surface resistance than a surface resistance of the first spacers.

4. The image display apparatus according to claim 1, wherein the first spacers protrude on the first surface of the grid between the beam passage apertures, and the second spacers protrude on the second surface of the grid between the beam passage apertures in alignment with the first spacers.

5. The image display apparatus according to claim 1, wherein the surfaces of the grid and inner surfaces of the beam passage apertures are high-resistance surface treated.

6. An image display apparatus comprising:
a first substrate having an image display surface;
a second substrate arranged opposite to the first substrate with a gap therebetween, and provided with a plurality of electron sources which excite the image display surface;
a grid provided between the first and second substrates, and having a first surface opposing the first substrate, a second surface opposing the second substrate and a plurality of beam passage apertures respectively opposing the electron sources;
a plurality of first spacers which are columnar, protrude from the first surface of the grid and abut against the first substrate; and
a plurality of second spacers which are columnar, protrude from the second surface of the grid and abut against the second substrate,
each of the first spacers abutting against the first substrate via a height buffer layer having a lower resistance than that of the first spacers.

7. The image display apparatus according to claim 6, wherein the second spacers have a lower surface resistance than a surface resistance of the first spacers.

8. The image display apparatus according to claim 7, wherein the first spacers protrude on the first surface of the grid between the beam passage apertures, and the second spacers protrude on the second surface of the grid between the beam passage apertures in alignment with the first spacers.

9. The image display apparatus according to claim 6, wherein the surfaces of the grid and an inner surface of each aperture are high-resistance surface treated.
